(19) United States
(12) Patent Application Publication
(10) Pub. No.: US 2015/0303368 A1
(43) Pub. Date: Oct. 22, 2015

(54) METHOD OF REPAIRING DEFECT IN SUPERCONDUCTING FILM, METHOD OF COATING SUPERCONDUCTING FILM, AND SUPERCONDUCTING FILM FORMED BY THE METHOD

(71) Applicant: Industrial Technology Research Institute, Hsinchu (TW)

(72) Inventors: Kun-Ping Huang, Miaoli County (TW); Hsi-Chuan Chen, Yilan County (TW); Chiang-Hsiung Tong, New Taipei City (TW); Chih-Wei Luo, Hsinchu City (TW); Wen-Yen Tzeng, Kaohsiung City (TW)

(21) Appl. No.: 14/332,307

(22) Filed: Jul. 15, 2014

(30) Foreign Application Priority Data
Apr. 17, 2014 (TW) 103114060

(51) Int. Cl. H01L 39/24; H01B 13/00; H01L 39/12; H01B 12/06

(52) U.S. Cl. CPC H01L 39/2448; H01B 12/06; H01B 13/0036; H01L 39/126; H01L 39/128; H01L 39/2438

(57) ABSTRACT

A method of repairing defect in a superconducting film, a method of coating a superconducting film, and a superconducting film formed by the method are prepared. The method of repairing defect includes detecting the superconducting film during a manufacturing process thereof. When a defect therein is detected, a repairing structure with superconductivity is formed on a position of the defect.

### CROSS-REFERENCE TO RELATED APPLICATION

This application claims the priority benefit of Taiwan application no. 103114060, filed on Apr. 17, 2014. The entirety of the above-mentioned patent application is hereby incorporated by reference herein and made a part of this specification.

### TECHNICAL FIELD

The disclosure relates to a method of repairing defects in a superconducting film, a method of coating superconducting film, and a superconducting film formed by the method.

### BACKGROUND

Generally, a conduction current of a superconducting film below a critical temperature has a resistance being zero, which will not heat up a conducting line by increases in currents to cause reduction in current density due to rising of the resistance. However, the superconducting film is practically of a single-crystal structure, which is prone to defect that causes reduction in current density during a manufacturing process.

Accordingly, one major solution is to simply give up defect portions, which will greatly influence a yield rate of the superconducting films. In addition, some technologies have also been developed to bond two separated superconducting films together through an electrical bonding method. Nevertheless, such technologies can only maintain a conductive property thereof yet still losing its high temperature superconductivity, which only creates more costs for maintaining (lowering) the temperature.

### SUMMARY

A method of repairing defect in a superconducting film according to the disclosure includes: during a manufacturing process of the superconducting film, detecting the superconducting film; and when a defect in the superconducting film is detected, forming a repairing structure with superconductivity on a position of the defect.

A superconducting film of the disclosure is manufactured by afore-said method, wherein the superconducting film has a repairing structure with superconductivity.

A method of coating a superconducting film of the disclosure is capable of forming a superconducting film having a predetermined thickness, and the method includes: coating a first superconducting film by a metal organic chemical vapor deposition (MOCVD); and coating a second superconducting film on the first superconducting film by a pulsed laser deposition (PLD).

Several exemplary embodiments accompanied with figures are described in detail below to further describe the disclosure in details.

### BRIEF DESCRIPTION OF THE DRAWINGS

FIG. 1 is a diagram illustrating steps of repairing defect in a superconducting film according to an exemplary embodiment.

FIG. 2A to FIG. 2B are cross-sectional diagrams illustrating a repairing method according to above exemplary embodiment.

FIG. 3 is a cross-sectional diagram illustrating another repairing method according to above exemplary embodiment.

FIG. 4 is a resistance-temperature diagram (RT diagram) of the superconducting film after repairing in Experiment 1.

FIG. 5 is a RT diagram of the superconducting film after repairing in Experiment 2.

FIG. 6 is a RT diagram of the superconducting film after repairing in Experiment 3.

FIG. 7A and FIG. 7B are cross-sectional diagrams illustrating a method of coating a superconducting film according to another exemplary embodiment.

### DETAILED DESCRIPTION

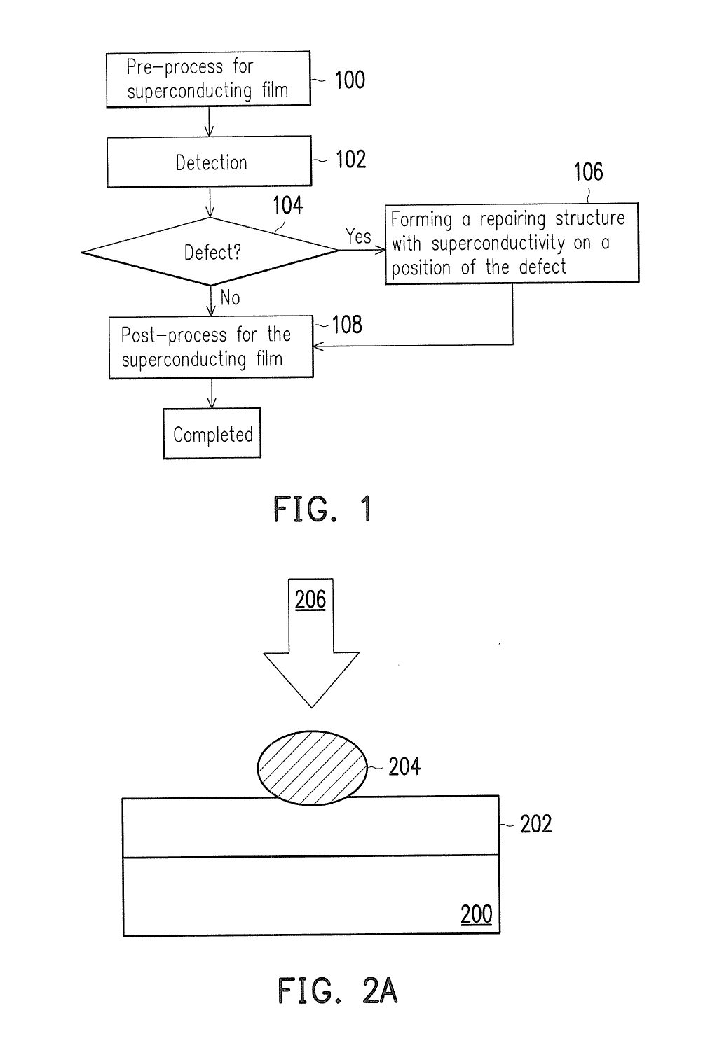

FIG. 1 is a diagram illustrating steps of repairing defect in a superconducting film according to an exemplary embodiment.

Referring to FIG. 1, in a method of repairing defect in a superconducting film according to the present embodiment, the superconducting film is detected during a manufacturing process of the superconducting film. Accordingly, in step 100, first, a pre-process for the superconducting film is performed. Take the superconducting film having yttrium barium copper oxide (YBCO) as an example, the pre-process thereof may include substrate producing, buffer deposition, YBCO precursor coating, precursor decomposition, YBCO reaction, etc. The pre-process for the superconducting film refers to the processes before detection, and generally refers to procedures of forming the superconducting film which may be produced in a manner of roll-to-roll (R2R), but the disclosure is not limited thereto. Further, a material of the superconducting film is, for example, a high temperature superconducting material such as bismuth strontium calcium copper oxide (Bi₂Sr₂Ca₂Cu₃O₁₀, BSCCO), thallium barium calcium copper oxide (Tl₂Ba₂Ca₂Cu₃O₁₀, TBCCO), or mercury barium calcium copper oxide (Hg₁₂Tl₃Ba₃₀Ca₃₀Cu₄₅O₁₂₇, HBCCO) in addition to YBCO mentioned above.

Next, in step 102, the detection is performed, in which a detecting method may be, for example, an X-ray detection or a 4-point probe detection, but the disclosure is not limited thereto. When a defect in the superconducting film is detected, proceeding to step 106; otherwise, proceeding to step 108 if the defect is not detected.

In step 106, a repairing structure with superconductivity is formed on a position of the defect, wherein a material of the repairing structure with superconductivity is, for example, a high temperature superconducting material such as yttrium barium copper oxide (YBCO), bismuth strontium calcium copper oxide (BSCCO), thallium barium calcium copper oxide (TBCCO), or mercury barium calcium copper oxide (HBCCO). The material of the repairing structure with superconductivity may be identical to the material of the superconducting film or different from the material of the superconducting film. Step 106 may be performed by various methods, and contents regarding the same will be described in detail as follows.

In step 108, a post-process for the superconducting film is performed. Take the superconducting film having YBCO as an example, the post-process thereof may include O₂ annealing, Ag deposition, lamination, web slitting and so on. The post-process for the superconducting film refers to a process after repairing, and generally refers to procedures after forming the superconducting film, but the disclosure is not limited thereto.

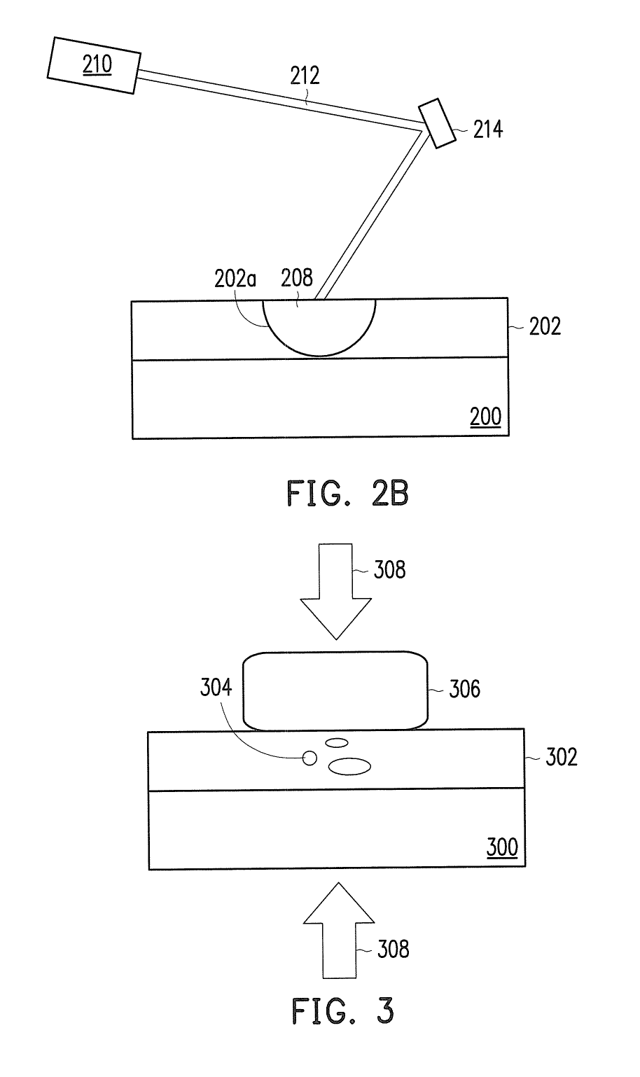

FIG. 2A to FIG. 2B are cross-sectional diagrams illustrating a repairing method according to aforementioned exemplary embodiment.

Referring to FIG. 2A, a superconducting film 202 is formed on a substrate 200. In case a defect 204 (e.g., a foreign substance type defect, such as dust and powdery dirts) is found after the detection (referring to step 102 of FIG. 1), the superconducting film 202 at the position of the defect 204 may be removed by a method such as a laser etching 206. At the same time, the defect 204 may also be removed.

Next, referring to FIG. 2B, a repairing structure with superconductivity 208 is formed by a thin film deposition process, and the repairing structure with superconductivity 208 is formed in a removed portion 202a of the superconducting film 202. However, the disclosure is not limited to the above. The repairing structure with superconductivity 208 may also extend to be formed on the superconducting film 202. Said thin film deposition process is, for example, a pulsed laser deposition (PLD). Accordingly, a laser source 210 and a target material 214 are illustrated in the drawing. When a high power pulsed laser 212 bombards the target material 214, the target material 214 is vaporized and deposited at a specific position on the substrate 200.

In another embodiment, if the defect itself is not big or the defect exists inside the superconducting film 202, the step of removing in FIG. 2A may be omitted, and the thin film deposition process of FIG. 2B is directly performed on the position of the defect 204 instead.

FIG. 3 is a cross-sectional diagram illustrating another repairing method according to aforementioned exemplary embodiment.

In FIG. 3, if a defect 304 is detected (referring to step 104 of FIG. 1) in a superconducting film 302 formed on a substrate, a method of forming a repairing structure with superconductivity 306 includes, for example, placing the repairing structure with superconductivity 306 on a position of the defect 304 followed by performing a microwave heating thereto. Accordingly, the repairing structure with superconductivity 306 may be directly bonded to the superconducting film 302. Moreover, a pressure 308 may also be applied to an overlapping portion of the repairing structure with superconductivity 306 and the superconducting film 302 while utilizing the microwave heating (e.g., a pressure of >11 kg/cm² is applied), and said pressure is preferably less than a pressure causing breakage or damage to the repairing structure with superconductivity 306 and the superconducting film 302. In addition, the superconducting film 302 at the position of the defect 304 may first be removed as illustrated in FIG. 2A before the microwave heating is performed, and followed by bonding the repairing structure with superconductivity 306 to the superconducting film 302.

Aforementioned two repairing methods as proposed by the disclosure may both be integrated in production line of roll-to-roll (R2R).

Experiments are provided below for verifying effects of the disclosure, but the scope of the disclosure is not limited by the following experiments.

Experiment 1

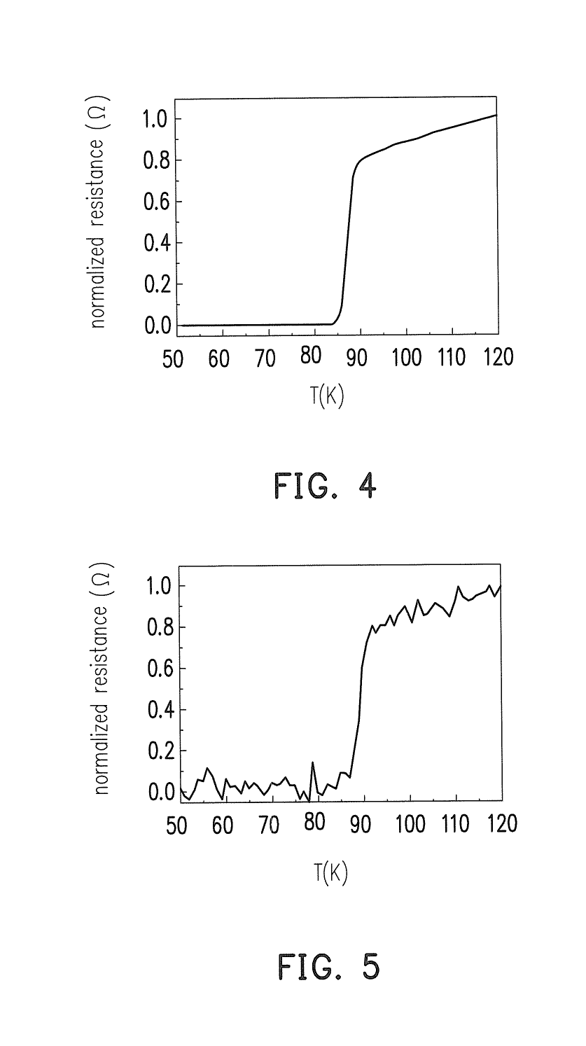

A part of an YBCO thin film on the substrate is removed by utilizing a pulsed laser, and a RT diagram (resistance-temperature diagram) thereof is measured. It is then confirmed that the YBCO thin film has lost the conductive property at a damaged position which becomes an insulator. Next, one layer of the YBCO thin film is re-coated on the removed portion, and a RT diagram thereof is measured, as shown in FIG. 4.

Before repairing the superconducting film and after removing the superconducting film, the superconducting film completely loses its superconductivity. In other words, phenomenon of zero resistance is still not shown after the temperature is dropped to the absolute temperature 2K. Yet, after repairing the superconducting film, the high temperature superconductivity is restored as shown by FIG. 4 in which the critical temperature reaches 85K (>77K).

Experiment 2

A RT diagram of a commercial YBCO thin film with defect is directly measured. It is then confirmed that the commercial YBCO thin film has lost the conductive property at a damaged position which becomes an insulator. Next, one layer of the YBCO thin film is re-coated on the YBCO thin film with defect, and a RT diagram thereof is measured, as shown in FIG. 5.

Before repairing the superconducting film, the superconducting film completely loses its superconductivity. Yet, after repairing the superconducting film, the high temperature superconductivity is restored as shown by FIG. 5 in which the critical temperature reaches 85 K (>77 K).

Experiment 3

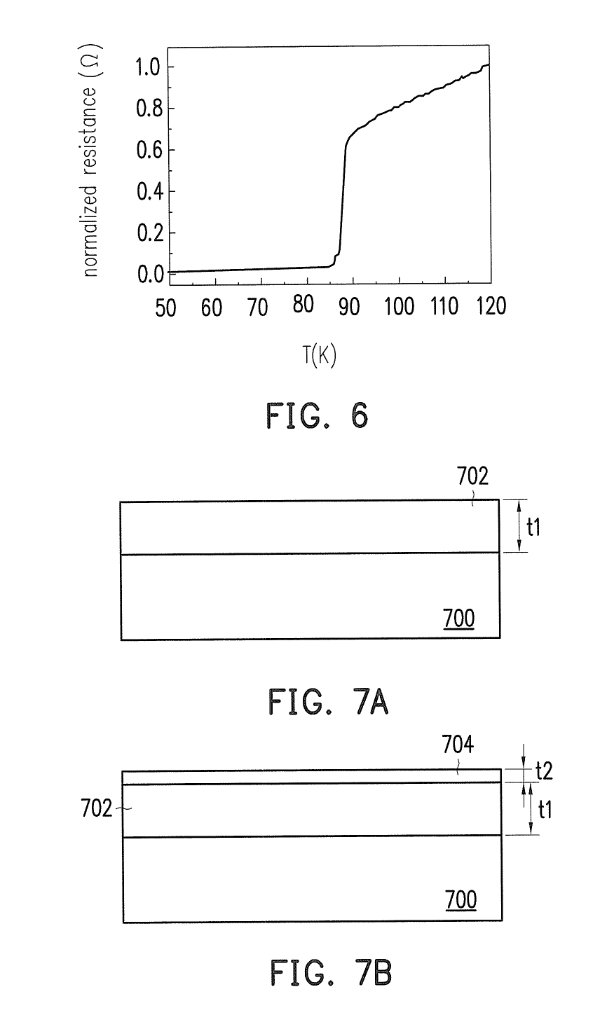

A RT diagram of an YBCO thin film with defect is directly measured. It is then confirmed that the YBCO thin film has lost the conductive property at a damaged position which becomes an insulator. Next, a piece of the repairing structure with superconductivity is directly placed on the YBCO thin film with defect at where above the defect inside the superconducting film, followed by bonding them together by the microwave heating, and a RT diagram thereof is measured, as shown in FIG. 6.

Before repairing the superconducting film, the superconducting film completely loses its superconductivity. Yet, after repairing the superconducting film, the high temperature superconductivity is restored as shown by FIG. 6 in which the critical temperature reaches 85 K (>77K).

FIG. 7A and FIG. 7B are cross-sectional diagrams illustrating a method of coating a superconducting film according to another exemplary embodiment.

Referring to FIG. 7A, first, a first superconducting film 702 is coated on a substrate 700 by a metal organic chemical vapor deposition (MOCVD), and a thickness t1 of the first superconducting film 702 is, for example, 70% to 90% of a predetermined thickness of a desired superconducting film. A material of the first superconducting film 702 is, for example, yttrium barium copper oxide (YBCO), bismuth strontium calcium copper oxide (BSCCO), thallium barium calcium copper oxide (TBCCO), or mercury barium calcium copper oxide (HBCCO).

Next, referring to FIG. 7B, a second superconducting film 704 is coated on the first superconducting film 702 by a pulsed laser deposition (PLD), and a thickness t2 of the second superconducting film 704 is, for example, 10% to 30% of the predetermined thickness of the desired superconducting film. A material of the second superconducting film 704 is, for example, yttrium barium copper oxide (YBCO), bismuth strontium calcium copper oxide (BSCCO), thallium barium calcium copper oxide (TBCCO), or mercury barium calcium copper oxide (HBCCO). The material of the second superconducting film 704 may be identical to the material of the first superconducting film 702 or different from the material of the first superconducting film 702.

In summary, regardless of whether a defect portion is removed first or not, the repairing method the disclosure is capable effectively repairing the superconductivity by subsequent repairing techniques, so that critical temperature may be greater than 77K for restoring the high temperature superconductivity. As a result, the techniques of the disclosure may substantially increase the yield rate of the superconducting film thereby reducing the costs. Furthermore, since two processes are adopted in the coating method of the disclosure, the yield rate of the superconducting film may be further increased.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A method of repairing a defect in a superconducting film, comprising:
detecting the superconducting film during a manufacturing process of the superconducting film; and
forming a repairing structure with superconductivity on a position of the defect if the defect in the superconducting film is detected.

2. The method of repairing a defect in the superconducting film of claim 1, wherein before the step of forming the repairing structure with superconductivity, the method further comprises removing the superconducting film at the position of the defect.

3. The method of repairing a defect in the superconducting film of claim 2, wherein a method of removing the superconducting film at the position of the defect comprises a laser etching.

4. The method of repairing a defect in the superconducting film of claim 1, wherein a material of the superconducting film and a material of the repairing structure with superconductivity each comprises yttrium barium copper oxide (YBCO), bismuth strontium calcium copper oxide (Bi₂Sr₂Ca₂Cu₃O₁₀, BSCCO), thallium barium calcium copper oxide (Tl₂Ba₂Ca₂Cu₃O₁₀, TBCCO), or mercury barium calcium copper oxide (Hg₁₂Tl₃Ba₃₀Ca₃₀Cu₄₅O₁₂₇, HBCCO).

5. The method of repairing a defect in the superconducting film of claim 1, wherein a method of forming the repairing structure with superconductivity comprises a thin film deposition process.

6. The method of repairing a defect in the superconducting film of claim 5, wherein the thin film deposition process comprises a pulsed laser deposition (PLD).

7. The method of repairing a defect in the superconducting film of claim 1, wherein a method of forming the repairing structure with superconductivity comprises:
placing the repairing structure with superconductivity at the position of the defect; and
directly bonding the repairing structure with superconductivity to the superconducting film by utilizing a microwave heating.

8. The method of repairing defect in the superconducting film of claim 7, wherein the microwave heating further comprises: applying a pressure to an overlapping portion of the repairing structure with superconductivity and the superconducting film.

9. A superconducting film, manufactured by the method of claim 1, wherein the superconducting film has the repairing structure with superconductivity.

10. The superconducting film of claim 9, wherein the repairing structure with superconductivity is located at the position of the defect.

11. The superconducting film of claim 9, wherein the repairing structure with superconductivity is directly bonded to the superconducting film.

12. A method of coating a superconducting film, for forming a superconducting film having a predetermined thickness, and the method comprising:
coating a first superconducting film by a metal organic chemical vapor deposition (MOCVD); and
coating a second superconducting film on the first superconducting film by a pulsed laser deposition (PLD).

13. The method of coating the superconducting film of claim 12, wherein a material of the first superconducting film and a material of the second superconducting film each comprises yttrium barium copper oxide (YBCO), bismuth strontium calcium copper oxide (BSCCO), thallium barium calcium copper oxide (TBCCO), or mercury barium calcium copper oxide (HBCCO).

14. The method of coating the superconducting film of claim 12, wherein a thickness of the first superconducting film is 70% to 90% of the predetermined thickness, and a thickness of the second superconducting film is 10% to 30% of the predetermined thickness.
